(19) United States
(12) Patent Application Publication
(10) Pub. No.: US 2026/0072107 A1
(43) Pub. Date: Mar. 12, 2026

(54) MAGNETIC RESONANCE SYSTEM AND CRYOGEN-FREE MAGNET ASSEMBLY THEREFOR

(71) Applicant: CRYOGENIC LIMITED, London Greater London (GB)

(72) Inventors: Eugeny Kryukov, London (GB); Jeremy Good, London (GB)

(73) Assignee: CRYOGENIC LIMITED, London Greater London (GB)

(21) Appl. No.: 19/160,297

(22) PCT Filed: Feb. 27, 2024
(86) PCT No.: PCT/GB2024/050528

§ 371 Date: Aug. 27, 2025

(30) Foreign Application Priority Data
Feb. 27, 2023 (GB) 2302817.8
Feb. 27, 2024 (WO) 2024180328

(51) Int. Cl. G01R 33/38; G01R 33/3815; G01R 33/3875; H01F 6/06

(52) U.S. Cl. CPC G01R 33/3804; G01R 33/3815; G01R 33/3875; H01F 6/06

(57) ABSTRACT

A magnetic resonance system comprises a magnet (210) cooled by a GM or pulse tube mechanized refrigerator which avoids the use of any liquid cryogens. As no reservoir is required, the cryostat (200) is more compact with better access to the central magnetic field, and allows the magnet (210) to be installed where there is limited ceiling height. The magnetic field to be changed at will or switched off, in contrast to liquid cooled magnets that are always on. Magnet temperature can also be changed while the magnet is at field, and this helps to get a stable field with time rather quickly, compared to the very long stabilizing time of liquid helium cooled magnets.

### TECHNICAL FIELD

The present invention relates to a magnetic resonance system and to a cryogen-free magnet assembly therefor. The preferred embodiments relate to the use of a cryogen free magnet (dry magnet) in the field of Solid State Nuclear Magnetic Resonance (SS NMR) spectroscopy, although the invention can also be used for other Magnetic Resonance (MR) applications and any other experimental techniques requiring a superconducting magnet with a large stable magnetic field such as MRI.

### BACKGROUND TO THE INVENTION

Nuclear Magnetic Resonance (NMR) systems are used for the non-destructive acquisition of structural and dynamic information of materials at the atomic level. NMR is widely used in science to study materials, biological samples and in medicine.

The magnet systems used in NMR are historically superconducting magnets, kept cold by immersing the superconducting coils in a bath of liquid helium, which is an expensive consumable. They are referred to as wet magnets hereinafter.

The cost and availability of liquid cryogens, more specifically liquid helium, in recent years has caused an increase in the cost of operation of NMR laboratories and a continuous concern by users on whether the liquid helium is available at any time.

The need for a solution has led to the development of a cryogen-free magnet. Such magnets not only can eliminate these issues, but they also present the user with new advantages, such as the use of the magnet at various fields, the option to insert a probe either from the top or the bottom of the magnet and a simplified requirement for the installation of the magnet system in a laboratory. Liquid magnets are filled with liquid helium using a double-walled syphon that must be inserted into the top of the cryostat. This requires a room with a high ceiling.

### SUMMARY OF THE PRESENT INVENTION

The present invention seeks to provide an improved a magnetic resonance system and cryogen-free magnet assembly therefor.

According to an aspect of the present invention, there is provided a magnetic resonance system including a cryostat comprising:
a magnet assembly,
a cooling assembly comprising an integrated cold head and a compressor, with a pulse tube refrigerator, operable to provide cooling of the magnet assembly.

The system is preferably a NMR magnet system.

Advantageously, the pulse tube refrigerator is a G-M (Gifford McMahon) or pulse tube mechanized refrigerator.

The cryostat is preferably free of liquid cryogens, that is the magnet assembly is a dry magnet assembly.

Preferably, the system comprises a processor unit connected to a power supply unit coupled to the magnet assembly, wherein the control unit is operable to control the supply unit to change a magnetic field generated by the magnet assembly or to switched off the magnetic field.

The system preferably comprises a temperature controller operable to change magnet temperature while the magnet assembly is operational.

Advantageously, the system comprises a cryostat housing having a top and a base and provided with a magnet assembly bore, wherein the bore is accessible from the top or from the base.

Preferably, the cryostat housing comprises a wall, from which internal components of the cryostat, including the magnet assembly and the bore, are isolated by thermal shielding.

The magnet coils of the magnet assembly are preferably disposed at a centre of the cryostat.

There are preferably provided current supply leads permanently connected to the magnet assembly. In the preferred embodiments, the current supply leads are made of high-temperature superconducting material.

There is preferably provided a power supply unit configured to enable controlled ramping of supply current to the magnet assembly.

In a practical embodiment, the magnet assembly comprises a central superconducting wire solenoid and a set of secondary windings (or shims) operable to adjust a homogeneity of a main magnet field produced by the central superconducting wire solenoid. It may comprise a set of eight or more secondary windings or shims, including 11 or 13.

Advantageously, a sample area is located at a centre of a field generated by the magnet assembly and reachable either from a top or a bottom of the cryostat.

The magnet assembly preferably comprises at least one superconducting shim coil and at least one warm shim winding disposed in a bore of a main magnet winding of superconducting wire. It may comprise a set of eight superconducting correction coils disposed around the main magnet winding, the correction coils representing first and second order corrections in Z, Z2, X, Y, ZX, ZY, XY and X2-Y2 directions.

The system may comprise a room temperature shim stack mounted inside a bore of the magnet assembly.

The processor unit is preferably configured to drive the magnet assembly to generate different magnetic fields.

In a practical embodiment, the system comprises current supply leads including first and second lead sections, each spanning a different temperature range, the first section optionally having a conductor made of copper and/or brass, the second section optionally having an HTS conductor.

Preferably, the processing unit is configured to apply a correction field to compensate for field changes as a function of time.

In a preferred embodiment, the cryostat comprises:
a compressor having a first flex connected to the cold head of the cryostat and a second flex line connected to a pressure transducer coupled to a control unit;
the control unit comprises a signal amplifier coupled to the pressure transducer and configured to amplify a transducer signal;
an arbitrary waveform generator and signal generator unit connected to the signal amplifier and to an instrument control processor unit, the instrument control processor unit being configured to generate an arbitrary waveform generator control (USB) signal;
the signal generator unit comprising a first output providing a start acquisition signal to an NMR spectrometer, and a second output providing a correction waveform signal to a break-out box.;
the instrument control processor unit being connected to the NMR spectrometer and configured to provide control data to the NMR spectrometer;
the NMR spectrometer comprising an output line providing shim current data to a shim power supply, the shim power supply being configured to set shim currents to the breakout box, which together with the Zo correction waveform signal is configured to output shim current control signals with a correction factor to a shim stack of the magnet assembly.

Preferably, the pressure transducer is configured to provide a timing signal operable to synchronize a NMR spectrometer to a cold head frequency and to cause control unit to create and drive a compensation current to stabilise a magnetic field at a sample location.

The system may be a Solid State Nuclear Magnetic Resonance (SS NMR) spectroscopy system.

According to another aspect of the present invention, there is provided a cryogen-free magnet assembly for a magnetic resonance system including a cryostat comprising:
a magnet,
a cooling assembly comprising an integrated cold head and a compressor operable to provide cooling of the magnet.

The magnet is preferably cooled by a GM (Gifford-McMahon) or pulse tube mechanized refrigerator which avoids the use of any liquid cryogens. As no reservoir is required, the cryostat is more compact with better access to the central magnetic field and allows the magnet to be installed where there is limited ceiling height. This design allows the magnetic field to be changed at will or switched off, in contrast to liquid cooled magnets that are always on. The magnet temperature can also be changed while the magnet is at field, and this helps to get a stable field with time rather quickly, compared to the very long stabilizing time of liquid helium cooled magnets.

Other aspects and advantageous features of the teachings herein will become apparent to the person skilled in the art from the specific description that follows.

### BRIEF DESCRIPTION OF DRAWINGS

Embodiments of the present invention are described below, by way of example only, with reference to the accompanying drawings, in which:

FIG. 1 is a schematic diagram in cross-section of an example of wet magnet assembly with a helium transfer syphon, ready to be inserted into a cryostat;

FIG. 2 is a schematic diagram in cross-section of an embodiment of a much smaller cryostat used with a cryocooled magnet;

FIG. 3 is a schematic diagram showing a cross-sectional view of a preferred embodiment of magnet assembly for the cryostat of FIG. 2;

FIG. 4 is a graph of field settling with time; and

FIG. 5 is a schematic diagram showing the use of a trigger to offset magnetic effects of the cold head.

### DESCRIPTION OF THE PREFERRED EMBODIMENTS

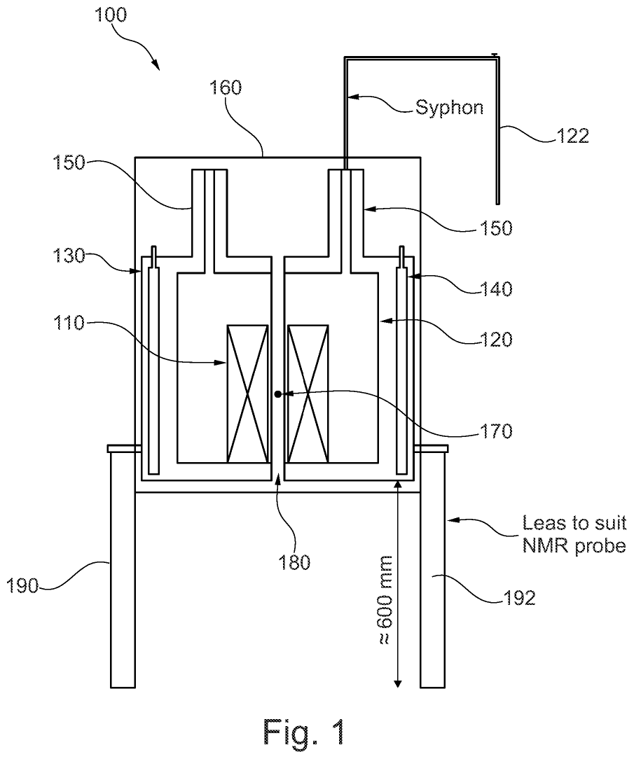

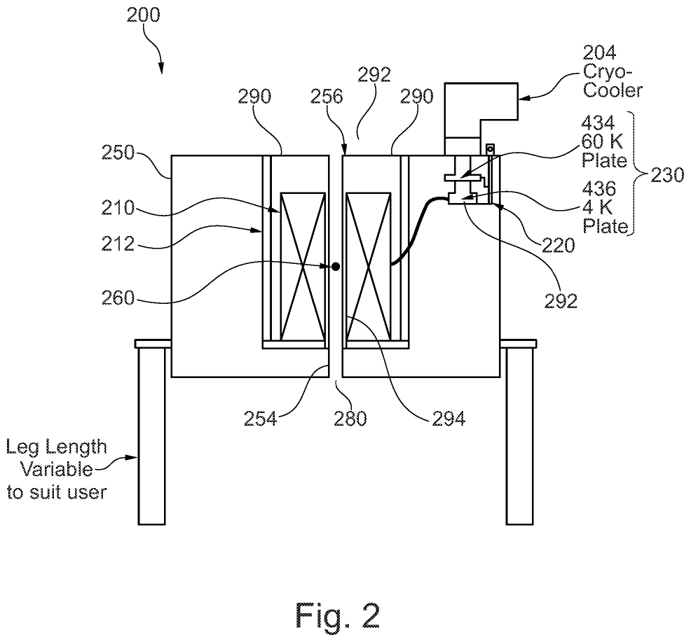

FIGS. 1 and 2 respectively show in cross-section a wet and a dry magnet.

Referring first to FIG. 1, in the wet magnet assembly 100, the windings of superconducting wire 110 used to generate the field are submerged in a bath 120 of liquid helium, supplied via a syphon 122. The vessel 110 providing the bath containing the helium is housed inside a second vessel 130 which contains liquid nitrogen 140. Both vessels 120, 130 are suspended on neck tubes 150 inside the main cryostat 160 to limit any thermal connection between the liquid helium container 120 and the outside wall of the cryostat 160. The space between the vessels 120, 130 and the cryostat body 160 is under vacuum. There are no direct permanent electrical connections between the winding 110 and the outside of the cryostat 160 since current leads would cause a thermal link between the magnet 110 and the outside world. This arrangement requires that the coils 110 sit close to the bottom of the cryostat 160, and that NMR probes 170 be inserted from the bottom 180. Legs 190, 192, of a height of around 600 millimetres, support the cryostat 160 and provide a sufficient height to enable access for the NMR probes. The two cylindrical necks 150 at the top of the cryostat 160 are used for the purpose of filling the magnet with cryogens or inserting the current leads. They are long, and the tubes that support the magnet and through which the helium liquid evaporates are thin walled, normally stainless steel. Their length is determined by the need to reduce to a minimum the heat load from room temperature to 4 K.

A clearance of one metre is necessary above the magnet 110 to give space for the insertion of the fill tube and the current leads.

As a consequence, the assembly 100 typically requires a room ceiling height H of around 3 metres.

Referring now to FIG. 2, this shows in schematic form an embodiment of dry magnet assembly 200. As will be apparent in FIG. 2, with the arrangement taught in the present application, there is no need for the long necks 150 of the wet magnet apparatus 100, since the magnet 210 does not need to be filled with cryogens and the current leads 220 can be permanently installed in the cryostat 250.

The NMR magnet system shown in FIG. 2 is provided with an integrated cold head and a compressor 204 which provides cooling for the cryostat 200. The internal components are isolated from the wall 250 of the cryostat 200 and the cylindrical bore 254 using thermal shielding. By eliminating the use of liquid cryogens, the need for specialized staff necessary for the maintenance of the magnet 210, that is regular refilling of the cryostat 200 with liquid helium and liquid nitrogen, is eliminated. The magnet 210 itself is maintenance free and the cold head 204 only requires service after every 20,000 hours of continuous use.

FIG. 2 shows how the magnet coils 210 in a cryogen free system can be placed at the centre of the cryostat 250 since there is no longer a need for extra space for the cryogens. The magnet 210 is disposed in this embodiment in a support structure 212 itself located in the cryostat 250, the latter being much smaller than a wet cryostat such as that shown in FIG. 1.

The position of the cold head 230 in relation to the coils 210 is defined in a manner that minimizes the effect of the cold head on the magnetic field. Eliminating the use of cryogen reduces the cost of operation of the system. There is no longer any need to purchase expensive cryogens, which are also hard to obtain in many countries outside Europe and North America. The dry magnet 210 also eliminates the need for specialized staff to perform the cryogen fills and the risk of a magnet quench during the fills due to excessive heating.

The vertical symmetry of the system 200 allows for access to the centre of the magnetic field with a probe 256 from either the top 270 or the bottom 280 of the magnet assembly.

FIG. 2 shows how the sample area can be reached at the centre of the field either from the top 270 or the bottom 280 of the magnet assembly. Positioning the sample 260 at the exact same place in the field is critical for measurement accuracy in comparative studies where multiple samples are being compared.

A top loaded probe 260 presents a significant improvement in the accurate positioning of the probe. There is no longer a concern that a bottom bracket disposed to hold a probe up as is required with a bottom fed probe as in the system of FIG. 1, is misaligned or not accurately secured. The probe assembly 256 can sit on the top surface 290 of the magnet assembly and can be maintained there by gravitational force. A small locator pin 292 can be used to assure that the probe assembly 256 is always located and fixed for rotation in the same manner.

By eliminating the need for liquids, the magnet 210 no longer requires large vessels filled with helium and space above it to fit the helium syphon that is used to refill the bath with liquid helium, as is required in the assembly of FIG. 1. The preferred design is therefore more compact and allows for the positioning of the magnet coils at the centre of the cryostat, as will be apparent in FIG. 2. This results in the possibility of inserting a probe 260 either from the top or the bottom of the magnet assembly. Being able to insert the probe from the top of the magnet assembly allows for a more reliable positioning of the sample in the magnetic field. In order to fill a wet magnet with liquid helium, a space of at least one metre above the top of the magnet is required. This is a problem for many buildings in which NMR might be used.

The cryogen free magnet system has current leads 220 which can be permanently connected to the magnet 210 at all times. The leads 220 are advantageously made of high-temperature superconducting material to reduce drastically the heat transfer to the cold magnet coils 210 from the top of the cryostat 200, which is at room temperature. This feature allows the operator to use the magnet 210 at any field between near zero and the maximum rated value of the magnet at any time. The field can be changed and stabilized in around an hour. A procedure involving field overshoots and periodic heating of the magnet's coil so as to reduce the field settling to about one hour after a field ramp up or down is achieved. The magnet system is advantageously provided with a power supply (not shown in FIG. 2) which allows the user to perform controlled ramping and also to protect the magnet circuitry in the event of a quench.

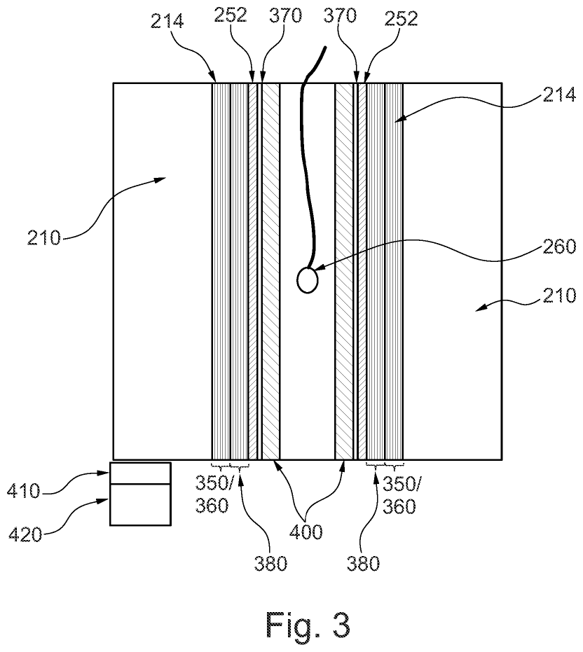

The magnetic field of the magnet 210 is generated by a central superconducting wire solenoid and a set of secondary windings which can be used to adjust the homogeneity of the main magnet field, described below in connection with FIG. 3. In some embodiments there may be a set of 8, 11 or 13 secondary windings, or shims.

The system is usually delivered with a second power supply (not shown in FIG. 2) which will provide the necessary currents for each superconducting shim coil.

The design of the magnet assembly is preferably optimized in order for the coil assembly to be as rigid as possible and reduce any temporal magnetic field distortion due to the cold head operation.

Reference is now made to FIG. 3, which shows in schematic form a cross-sectional view of a preferred embodiment of magnet assembly for the embodiment of cryostat of FIG. 2. The final magnetic field experienced by the sample 260 is the sum of a number of coils 350-360, some superconducting shim coils 350 and other warm shim windings 360 placed in the bore 214 of the magnet 210 at room temperature. The coil 352 generating the bulk of the field is a solenoid winding 352 of superconducting wire through which there is a room temperature bore tube 370 into which the NMR apparatus is placed. Due to some variation in the geometry of the wire and its fabrication, the field generated by the main coil 352 requires corrections in order to obtain an industry standard homogeneous field of 10° PPB in the area of interest. A set of eight superconducting correction coils 380 are placed in position around the main coil 352. They represent first and second order corrections in Z, Z2, X, Y, ZX, ZY, XY and X2-Y2. Finally, in order to further optimize the field for High Resolution NMR, a room temperature shim stack 400 is mounted inside the bore of the magnet. As many as 48 shims at room temperature may be used to balance the field and obtain the best homogeneity. The NMR probe 260 is then set inside this space.

The ability to ramp the magnet 210 up and down as desired or required for a particular use of the apparatus is a material advantage of the invention and teachings herein. The skilled person will appreciate that rate at which the magnet 210 can be ramped has limits which are dictated by the physics of the materials used to construct the coils. It is not unknown for high field superconducting magnets to fail by quenching of the magnetic field. High field coils operate with very high tensile forces on the windings. At times the stress causes movement of the winding, leading to local heating of the conductor above its transition temperature to the non-superconducting state. If any part of the coil does become non-superconducting and resistive, the heat generated by current in the resistive section rapidly spreads, the resistance causing the current flowing in the magnet to collapse and the magnetic field to be quenched.

When this happens in a wet magnet, the liquid helium is expelled from the cryostat and say 100 litres, a typical charge of liquid, becomes 70 cubic metres of gas, which can cause asphyxia and must be extracted from the building in a safe and secure fashion. After this, the magnet must be re-cooled with more liquid helium, the magnetic field re-energized and the shim coils all re-energized and balanced, which is a time consuming and expensive procedure.

With a dry magnet, by contrast, there is no dramatic or observable effect or risk to any person. The cryomagnet 200 will re-cool automatically and then experimental work can be restarted without difficulty.

The use of a cold head for cooling the superconducting coils instead of cryogens can introduce vibrations in the cryostat 200 which can cause temporal magnetic distortions. These distortions can affect the quality of the NMR signal and introduce artefacts in the data. It was found that the mechanical displacement of the magnet 210 inside the cryostat plays a major role in temporal magnetic field instability. Better mounting of the coils helps to reduce such instabilities to better than the 10 ppb level. However, the advantages of a system without liquid helium more than offsets the difficulty of using a cryocooler.

A traditional NMR magnet coil is installed in a liquid helium bath as described above and operates in the persistent mode (PM). There are no moving parts and therefore no vibration issues. However, in order to maintain a low helium boil off, the current leads to the magnet must be withdrawn once the magnet is energized. It is only possible to attain a highly stable and persistent magnetic field if all the joints between the different magnet sections are truly superconducting. This can be done but still it is common that a long time (up to several weeks) is required for the magnetic field to settle and the drift to drop to acceptable levels using conventional superconductive wires. As the field is never changed, this has to and can be accepted.

By contrast, a magnet assembly of the type disclosed herein can operate at different fields as required. This means that the time for the field to become stable is very important. The ability to set the field at any value, from very low to the maximum rated field, is such a useful feature that being able to have the field settle quickly is of great importance. A proper ramping procedure is feasible, which allows the assembly taught herein to reach quickly a stable field with a low drift as needed for NMR. When a magnet 210 is energized from zero to a certain field and is left to relax in Persistent Mode (PM), the field in the centre of the magnet's bore reduces. Conversely, if the magnet 210 is brought to target from a higher field, the relaxation is positive, that is the field at the magnet centre increases. The sign of the drift can be understood by considering screening currents in the superconducting filaments. When the field is ramping up, the flux does not fully penetrate into the filaments. Flux density at the centre of the filament is lower than the external magnetic field. This results in a negative filament magnetization. When the ramp is stopped, the magnetization currents decay via the process of flux creep, so that the negative magnetization reduces and more flux penetrates into the magnet winding. Since the integral flux through the central cross-section of the superconducting loop remains constant, more flux in the winding means less flux in the bore, hence the observed field decay. Coming from high field, there is higher density of flux at the filament centre and the conductor retains positive magnetization. The creep causes flux reduction in the winding and consequently the field increases in the magnet bore. Magnetic flux creep in superconductors is a thermally activated process. It is therefore possible to increase the rate by warming the magnet, and thus reduce the time necessary to approach stability.

In order to achieve stability, a procedure providing a small current overshoot and heating of the magnet has been devised. Such a procedure reduces the amount of time required to settle the magnet 210 to within about one hour after the field has been changed. This method can only be applied to cryogen free magnets since it requires heating the coil without any quench and adjusting the current in the magnet using the permanent leads. Another virtue of the cryocooled magnet 210 is that the base temperature of the magnet coil is lower than 4 Kelvin, often down to 3 Kelvin. The magnet temperature can be controlled using a temperature controller 410 and an electrical heater 420 that is thermally linked to the coil.

During a magnet ramp, an overshoot of, say, 0.19% might be applied for approximately 1 to 10 minutes, in a practical example around 6 minutes. The field is then set back to the required value and the coil is warmed up to 4.5K for 6 minutes.

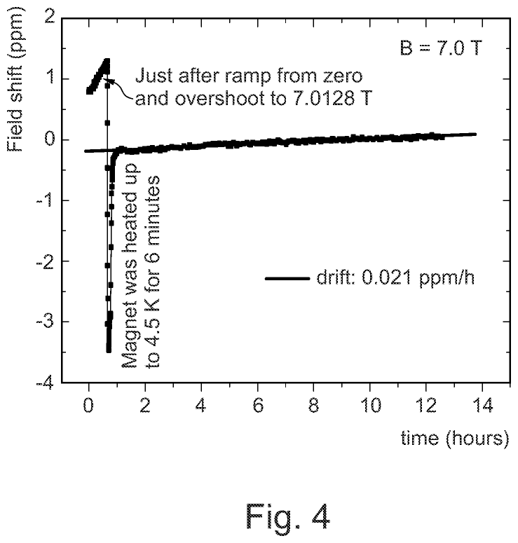

FIG. 4 shows a graph of the field magnitude over time on one such magnet. As can be seen, the field is very stable within a short period. Proceeding as described above advantageously relies on the current leads 220 being built into the magnet. Unlike in the case of a wet cryostat, the current leads 220 are preferably not made of a single removable conductor connecting to the coil and to the power supply. The leads 220/434,436 (see FIG. 2) are advantageously made of two sections, each spanning a different temperature range. The top section 434 from the top of the cryostat, is the warmest area within the vacuum space. Then a second section 436 from the first cooling stage 434 where the temperature is around 50K to the second cooling stage 436 which sit at about 3-4 K depending on the magnet type. For the first section 434, a conductor of copper and brass is used. For the second section 436, an HTS conductor, which is superconducting at 100 K, is used. It is preferably backed by a brass or stainless steel conductor for security, in case the HTS fails. As the current is carried by the superconductor, there is no heat generated at the second stage at 3-4 K, which means the magnet can be kept very cold. The result is a closed electric circuit which maximizes the ramping current efficiency and minimizes the thermal loss.

As there is some mechanical disturbance of the magnet 210, which can lead to a magnetic field variation with time due to the operation of the cryocooler, there is also an option to apply a correction field to compensate and avoid field changes as a function of time. This can be done by applying a small correction field to counterbalance the original field variation and give a stable field at the sample being investigated by NMR methods.

In order to give correct timing for the correction field the pressure of gas circulating through the cold head is preferably monitored. The operation of the cold head gives large fluctuations in the pressure of the circulating gas and so provides a good signal in time with the cold head working cycle.

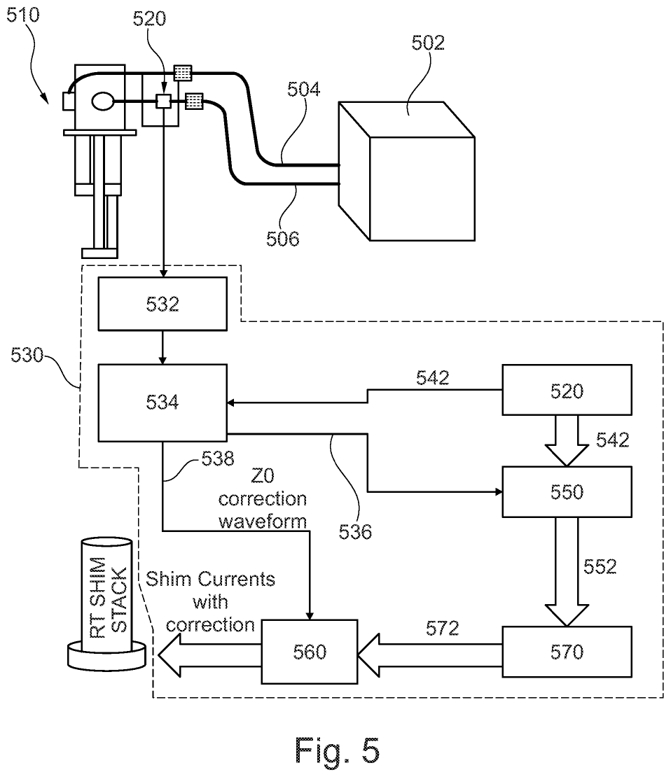

The preferred system and method are shown in the schematic diagram of FIG. 5.

The apparatus comprises a compressor 502 from which there emanates a first flex line 504 which connects to the cold head 510 of the cryostat 200. A second flex line 506 extends from the compressor 502 to pressure transducer 520, which is coupled to a control unit generally indicated at 530.

The control unit 530 comprises a signal amplifier 532 coupled to the pressure transducer 520 and configured to amplify the transducer signal to an appropriate level. An arbitrary waveform generator and TTL (transistor-transistor logic) signal generator unit 534 has a first input connected to the signal amplifier and a second input connected to an instrument control processor unit 540, which is configured to generate an arbitrary waveform generator control (USB) signal on line 542.

The signal generator unit 534 has a first output 536 which provides a TTL start acquisition signal to an NMR spectrometer 550. The signal generator unit 534 has a second output 538 which provides a Zo correction waveform signal to a break-out box 560. The instrument control processor unit 540 is connected to the NMR spectrometer 550 by an output line 542, configured to provide control data to the NMR spectrometer 550. The NMR spectrometer 550 has an output line 552 which provides shim current data to shim power supply 570. The power supply 570 outputs at 572 the set shim currents to breakout box 560, which together with the Zo correction waveform signal from line 538 outputs shim current control signals with the appropriate correction factor to the RT shim stack of the magnet assembly.

The system of FIG. 5 operates in the following manner. The pressure transducer 520 provides the timing signal, which is used in two ways. The first use is to synchronize the NMR spectrometer to the cold head frequency. That reduces artifacts in the NMR signal caused by field fluctuations. The second route is to use the function generator 530 to create and drive a compensation current into the room temperature shim coils 400 set inside the magnet bore. This directly stabilises the magnetic field at the sample. By means of this method the magnetic field is stabilised over the period in which the NMR signal is being excited and measured leading to cleaner and less noisy NMR spectra.

In practical embodiments, the temporal magnetic field distortion generated by the cold head operation can be removed and high quality Solid-State Magic Angle Spinning NMR results can be obtained with a cryogen-free magnet. The compact design of the cryogen-free magnets allows for the probe to be insertable either from the bottom (as in most NMR systems) or, more conveniently, from the top. The magnetic field settling time can be reduced down to an hour after a field ramp such that a single cryogen-free magnet can be used at different fixed fields. The magnetic field can be changed every day without compromising the measurement resolution.

The top loading ability of the cryostat assembly 200 turned out to be very convenient particularly in situations where sample is changed multiple times. Top loading allows for the handling and positioning of the probe more accurately, and for returning the sample to the same position as before, saving the time for extra shimming after a sample change.

It will be appreciated that access to the bore of the magnet can be from the top of the cryostat only. There in no need in all embodiments for there to be dual access, that is from the top and from the bottom of the cryostat.

The disclosures in British patent application number GB2302817.8, from which this application claims priority, and in the abstract accompanying this application, are incorporated herein by reference.

1. A magnetic resonance system including a cryostat, comprising:
a magnet assembly, and
a cooling assembly comprising an integrated cold head and a compressor, with a pulse tube refrigerator, operable to provide cooling of the magnet assembly;
wherein the compressor has a first flex line connected to the cold head of the cryostat and a second flex line connected to a pressure transducer coupled to a control unit;
wherein the control unit comprises a signal amplifier coupled to the pressure transducer and configured to amplify a transducer signal;
wherein the cryostat comprises an arbitrary waveform generator and signal generator unit connected to the signal amplifier and to an instrument control processor unit, the instrument control processor unit being configured to generate an arbitrary waveform generator control (USB) signal;
the signal generator unit comprising a first output providing a start acquisition signal to an NMR spectrometer, and a second output providing a correction waveform signal to a break-out box;
the instrument control processor unit being connected to the NMR spectrometer and configured to provide control data to the NMR spectrometer;
the NMR spectrometer comprising an output line providing shim current data to a shim power supply, the shim power supply being configured to set shim currents to the break-out box, which together with a ZO correction waveform signal is configured to output shim current control signals with a correction factor to a shim stack of the magnet assembly; and,
wherein the pressure transducer is configured to provide a timing signal operable to synchronize the NMR spectrometer to a cold head frequency and to cause the control unit to create and drive a compensation current to stabilise a magnetic field at a sample location.

2. (canceled)

3. The system according to claim 1, wherein the pulse tube refrigerator is a G-M (Gifford McMahon) or pulse tube mechanized refrigerator.

4. (canceled)

5. The system according to claim 1, wherein the cryostat is free of liquid cryogens so that the magnet assembly is a dry magnet assembly.

6. The system according to claim 1, comprising a processor unit connected to a power supply unit coupled to the magnet assembly, wherein the control unit is operable to control the supply unit to change a magnetic field generated by the magnet assembly or to switch off the magnetic field.

7. The system according to claim 1, comprising a temperature controller and a heater thermally linked to the magnet assembly and operable to increase magnet temperature while the magnet assembly is operational.

8. The system according to claim 1, comprising a cryostat housing having a top and a base and provided with a magnet assembly bore, wherein the bore is accessible from the top or from the base.

9. The system according to claim 8, wherein the cryostat housing comprises a wall, from which internal components of the cryostat, including the magnet assembly and the bore, are isolated by thermal shielding.

10. The system according to claim 1, wherein magnet coils of the magnet assembly are disposed at a centre of the cryostat.

11. The system according to claim 1, comprising current supply leads permanently connected to the magnet assembly.

12. The system according to claim 11, wherein the current supply leads are made of high-temperature superconducting material.

13. The system according to claim 1, comprising a power supply unit configured to enable controlled ramping of supply current to the magnet assembly.

14. The system according to claim 1, wherein the magnet assembly comprises a central superconducting wire solenoid and a set of secondary windings operable to adjust a homogeneity of a main magnet field produced by the central superconducting wire solenoid, optionally comprising a set of at least eight secondary windings.

15. (canceled)

16. The system according to claim 1, comprising a sample area located at a centre of a field generated by the magnet assembly and reachable either from a top or a bottom of the cryostat.

17. The system according to claim 1, wherein the magnet assembly comprises at least one superconducting shim coil and at least one warm shim winding disposed in a bore of a main magnet winding of superconducting wire, and optionally comprises a room temperature shim stack mounted inside a bore of the magnet assembly.

18. The system according to claim 17, comprising a set of eight superconducting correction coils disposed around the main magnet winding, the correction coils representing first and second order corrections in Z, Z2, X, Y, ZX, ZY, XY and X2-Y2 directions.

19. (canceled)

20. The system according to claim 1, comprising a processor unit configured to drive the magnet assembly to generate different magnetic fields.

21. The system according to claim 1, comprising current supply leads including first and second lead sections, each spanning a different temperature range, the first section optionally having a conductor made of copper and/or brass, the second section optionally having an HTS conductor.

22. The system according to claim 1, comprising a processing unit configured to apply a correction field to compensate for field changes as a function of time.

23. (canceled)

24. (canceled)

25. The system according to claim 1, wherein the system is a Solid State Nuclear Magnetic Resonance (SS NMR) spectroscopy system.

26. (canceled)
